(19) United States
(12) Patent Application Publication
(10) Pub. No.: US 2024/0189861 A1
(43) Pub. Date: Jun. 13, 2024

(54) MULTILAYER BARRIER FILM, ITS MANUFACTURE AND USE IN PHOTOVOLTAIC APPLICATIONS

(71) Applicant: BASF Coatings GmbH, Muenster (DE)

(72) Inventors: Edoardo MENOZZI, Basel (CH); Jan GEBERS, Basel (CH); Andrea GIRALDO, Basel (CH)

(21) Appl. No.: 18/554,122

(22) PCT Filed: May 5, 2022
(86) PCT No.: PCT/EP22/62097

§ 371 Date: Oct. 5, 2023

(30) Foreign Application Priority Data
May 6, 2021 (EP) 21172453.9

(51) Int. Cl. B05D 7/00; B05D 3/02; B05D 3/06; C23C 16/455; H01L 31/048

(52) U.S. Cl. CPC B05D 7/576; B05D 3/0254; B05D 3/067; C23C 16/45525; H01L 31/0481; B05D 2201/02; B05D 2502/00

(57) ABSTRACT

Disclosed herein is a multilayer barrier film for coating a transparent polymeric substrate (A), the multilayer barrier film (MLBF) including in the order from (B) to (C) to (D): one or more transparent, at least partially inorganic barrier layers (B), one or more transparent, radiation-cured (meth)acrylate layers (C), and one or more transparent, thermally-cured coating layers (D). TFurther disclosed herein is a multilayer barrier film (MLBF) coated substrate and methods for producing the multilayer barrier film (MLBF) and the multilayer barrier film (MLBF) coated substrate. Additionally disclosed herein is a use of MLBF the multilayer barrier film (MLBF) coated substrates in photovoltaic applications.

The invention relates to a multilayer barrier film (MLBF) for coating a transparent polymeric substrate. The invention further relates to a thus coated substrate and methods to manufacture the MLBF and MLBF coated substrate. Moreover, the invention relates to the use of the MLBF coated substrates in photovoltaic applications.

### BACKGROUND OF THE INVENTION

Polymeric films are widely used and useful in a broad range of industrial and consumer applications. Such films, for example, can be employed as transparent or tinted barrier films to protect different types of underlying substrates. Polymeric films, and particularly polymeric films made of semi-crystalline resins like for example polyester materials, offer many characteristics desirable in a barrier film. Among other properties, they exhibit clarity, flexibility, durability, toughness, pliability, formability, light weight and affordable costs.

Use of some of the most desirable polymeric films, however, can be severely limited for outdoor applications and other applications where the films are exposed to a prolongated source of light, moisture and temperature. For example, many polymeric films degrade when subjected to prolonged exposure to ultraviolet radiation (which occurs naturally during outdoor use or by exposure to fluorescent light or other UV-emitting light source) or when exposed to moisture at temperatures above their glass transition temperature.

CN 109421334 A discloses barrier materials comprising a polymeric substrate, an alumina layer or silicon dioxide layer thereon and a yellow light absorbing radiation cured layer thereon. However, such multilayer system is not suitable for long-term outdoor applications such as the use in photovoltaic applications.

U.S. Ser. No. 10/665,738 B2 provides a gas barrier film which can prevent the damage of an inorganic layer even in a case where the gas barrier film is used in a product which undergoes a step of applying pressure, heat, and the like. U.S. Ser. No. 10/665,738 B2 further relates to a solar cell using the gas barrier film, and a manufacturing method of the gas barrier film. The inorganic film can be an aluminum oxide film formed by plasma CVD such as Capacitively Coupled Plasma (CCP)-Chemical Vapor Deposition (CVD) and Inductively Coupled Plasma (ICP)-CVD, sputtering such as magnetron sputtering and reactive sputtering, or a vapor-phase deposition method such as vacuum vapor deposition. The protective layer formed on the inorganic film is a radiation-cured coating layer. However, even intended to be used for solar cells, the outer layer is not resistant enough for long-term stability outdoor applications, as e.g., evidenced by the DE 10 2011 113160 A1, which is discussed in the following paragraph.

DE 10 2011 113160 A1 discloses polyurethane layers made of hydroxyl-functional fluoropolymers cured with polyisocyanates and compares these with radiation-cured coating layers, both being applied directly on top of a polymethylmethacrylate substrate film. Thus, the fluoropolymer films are proposed as more rugged alternative to radiation-cured coating films, but not in combination with such films. Furthermore, the architecture, i.e., sequence of layers of the barrier films disclosed in DE 10 2011 113160 A1 significantly differs from the layer sequences in the above CN 109421334 A and U.S. Ser. No. 10/665,738 B2.

US 2011/0045193 A1 also discloses the use of a fluoropolymer-based layer in a barrier film. However, this document focusses on promoting the adhesion of such layers directly on a backsheet substrate, such as a polyester resin, by incorporating boron nitride to promote the adhesion. Radiation-cured layers are neither mentioned not envisaged in the barrier films disclosed in US 2011/0045193 A1.

Obviously, there remains a desire for articles containing a barrier film that exhibits improved light stability combine with higher barrier properties against moisture and also gases. There is still a need for MLBF coated substrates, which are long-term stable, particularly in outdoor applications and showing a good interlayer adhesion and reduced yellowing. Such MLBF coated substrates should be suitable as protective sheets in photovoltaic applications.

This type of protective sheets can preferably be used in applications like solar cell modules as front protective sheet (front sheet) or back protective sheet (back sheet) due to their lower weight, flexibility and advantageous costs; other possible applications are portable lighting devices, advance packaging for optoelectronics and displays like for example OLED screens.

### SUMMARY

The above aims of the present invention were achieved by providing a multilayer barrier film (MLBF) for coating a transparent polymeric substrate (A), the multilayer barrier film comprising in the order from (B) to (C) to (D) one or more transparent, at least partially inorganic barrier layers (B), one or more transparent radiation-cured (meth)acrylate layers (C), and one or more transparent thermally-cured coating layers (D).

The meaning of the term “for coating a transparent polymeric substrate” is that the multilayer barrier film is suitable as a coating for transparent polymeric substrates, but not limited to coating such substrates.

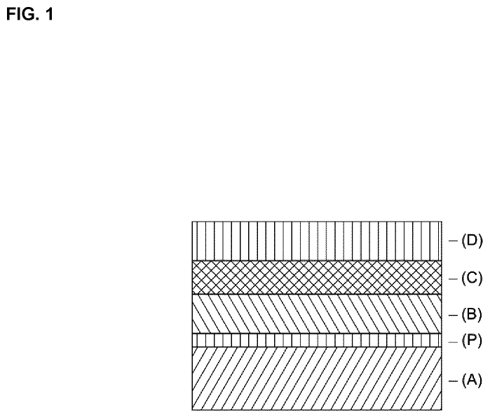

FIG. 1 shows a typical architecture of the MLBF on a substrate (A), whereby the substrate (A) is further coated with an optional planarization layer (P).

The order of the three mandatory layers being from (B) to (C) to (D) does not exclude the presence of further layers preceding layer (B), subsequent to layer (D) and/or between layers (B) and (C), and layers (C) and (D), respectively. Only in those embodiments of the invention where the multilayer barrier film consists of layers (B), (C) and (D), layer (C) is not only between layers (B) and (D), but also in direct contact with layers (B) and (D).

The term “at least partially inorganic” in view of the “at least partially inorganic barrier layers (B)” means that the layer or layers may be completely composed of inorganic material, but may also be composed of inorganic layers and organic layers, preferably in an alternating order.

The term “radiation-cured” in view of the one or more transparent radiation-cured (meth)acrylate layers (C) refers back to the radiation-curable nature of crosslinkable monomers, oligomers and polymers being used to produce the radiation-cured (meth)acrylate layers, i.e., the presence of (meth)acrylic groups before curing, i.e., crosslinking, which react with each other to form the radiation-cured (meth)acrylate layer. The term “(meth)acrylate” denotes for both “acrylate” and “methacrylate”.

The term “thermally-cured” in view of the coating layers (D) refers to a curing mechanism, where no radiation is involved and were a binder carrying reactive functional groups and a separate crosslinking agent carrying functional groups that are reactive towards the functional groups of the binder are involved in the curing mechanism.

The term “transparent” used in view of the layers and the substrate means that the layers and/or substrate are translucent, i.e., light-transmissive. The term “transparent” as used herein can be quantified by determination of the total luminous transmittance according to ASTM D 1003: 2013. Preferably, the thus determined total luminous transmittance of each layer of the MLBF, the MLBF itself and the herein below described MLBF-coated substrate is in the range from 80% to 99%, more preferred in the range from 85% to 98% and most preferred in the range from 90% to 97%.

In the following, the multilayer barrier film is also denoted as the “multilayer barrier film of the invention” or the “MLBF of the invention”.

Another object of the present invention is a multilayer barrier film coated substrate, comprising in this order a transparent polymeric substrate (A), one or more transparent, at least partially inorganic barrier layers (B), one or more transparent radiation-cured (meth)acrylate layers (C), and one or more transparent, thermally-cured outer coating layers (D).

In the following the multilayer barrier film coated substrate is also denoted as the “multilayer barrier film coated substrate of the invention” or the “MLBF coated substrate of the invention”.

Yet another object of the present invention is a method for producing a multilayer barrier film comprising the steps of
a. providing a substrate;
b. applying one or more inorganic layers on the substrate by one or more methods selected from chemical vapor deposition (CVD), physical vapor deposition (PVD), atomic layer deposition (ALD) and sputtering to form one or more transparent, at least partially inorganic barrier layers (B);
c. applying one or more radiation-curable (meth)acrylic coating compositions C on the one or more transparent, at least partially inorganic barrier layers (B) to form one or more transparent radiation-curable (meth)acrylate layers and curing said layer or layers to form one or more radiation-cured (meth)acrylate layer (C); and
d. applying one or more thermally-curable coating compositions D on the one or more radiation-cured (meth)acrylate layer (C) to form one or more thermally-curable coating layers D and curing said layer or layers to form the one or more transparent, thermally-cured coating layers (D);

not excluding additional steps between steps a. and b., steps b. and c. and steps c. and d.

In the following the method for producing a multilayer barrier film is also denoted as the “method for producing the multilayer barrier film of the invention” or the “method for producing the MLBF of the invention”.

Further object of the present invention is a method of producing a multilayer barrier film coated substrate by providing a transparent polymeric substrate (A) in the method of producing a multilayer barrier film according to the invention.

In the following the method for producing a multilayer barrier film coated substrate is also denoted as the “method for producing the multilayer barrier film coated substrate of the invention” or the “method for producing the MLBF coated substrate of the invention”.

Yet another object of the present invention is the use of MLBF of the invention or the MLBF coated substrate of the invention in photovoltaic applications.

In the following the use of MLBF of the invention or the MLBF coated substrate of the invention in photovoltaic applications is also denoted as the “use of the invention”.

Further preferred features and embodiments of the invention are disclosed in the dependent claims and the following detailed description.

### DETAILED DESCRIPTION

Multilayer Barrier Film and therewith Coated Substrate

As explained above, the multilayer barrier film of the present invention is suitable for coating a transparent polymeric substrate, but not limited to such substrates. Therefore, in the following, different types of substrates are disclosed which can be coated by the multilayer barrier film.

### Substrates

The substrates can be any solid material. These include for example metals, semimetals, oxides, nitrides, and polymers. It is also possible that the substrate is a mixture of different materials or a composite material.

However, polymers and particularly transparent polymers are preferred as substrates.

Suitable polymers include polyesters such as polyethylene terephthalate (PET), polybutylene terephthalate and polyethylene naphthalene-dicarboxylic acid (PEN); polyimides; polyacrylates such as polymethyl methacrylate (PMMA); polyacrylamides;

polycarbonates such as poly(bisphenol A carbonate); polyvinylalcohol and its derivatives like polyvinyl acetate or polyvinyl butyral; polyvinylchloride; polyolefins, which include polycycloolefins, such as polyethylene (PE), low density polyethylene (LDPE), linear low density polyethylene (LLDPE), polypropylene (PP) and polynorbornene; polysulfones, such as polysulfone (PSU), polyethersulfone (PES) and polyphenylene sulfone (PPSU); polyamides like polycaprolactam (PA6) or poly(hexamethylene adipic amide) (Nylon 66); cellulose derivatives such as hydroxyethyl cellulose, hydroxypropyl cellulose, methyl cellulose, methyl hydroxylpropyl cellulose or nitrocellulose; polyurethanes; epoxy resins; melamine formaldehyde resins; phenol formaldehyde resins. The term “polymers” includes copolymers made of two or more different kinds of monomers, such as poly(ethylene-co-norbornene) or poly(ethylene-co-vinylacetate).

Amongst the afore-mentioned polymers, transparent polymers from the group consisting of polyesters, polyolefins, polyamides and polysulfones are preferred; and polyesters such as PET are most preferred.

Preferably, the substrates, and particularly the polymeric substrates, should be stable to heat of at least 140° C.

The substrates can have any size and shape. Preferably the substrates, most preferred the polymeric substrates are in form of a transparent film. Preferred film thicknesses are in the range from 10 to 500 μm, more preferred in the range from 25 to 300 μm, and even more preferred in the range from 50 and 150 μm.

### Optional Planarization Layer (P)

The surface of the substrate, and particularly the substrate in form of a transparent polymeric film, is preferably of high planarity. High planarity in the context of the present invention means that the highest point on the surface is not more than 100 nm higher than the lowest point on the surface, preferably not more than 50 nm. The planarity can be measured for example with atomic force microscopy, preferably in tapping mode.

Substrates are often not available with high planarity, e.g., due to small scratches, or particles such as dust adhered to their surface. It is therefore preferred, that a planarization layer (P) is provided between the MLBF and the substrate to avoid damaging such as puncturing the MLBF. The planarization layer can additionally serve to better hold together the substrate and the MLBF, particularly upon bending or heating. Therefore, even if planarization is not necessary, a planarization layer (P) can be present on the substrate for the afore-mentioned reasons. In such case the order of layers is [substrate (A)]-(P)-(B)-(C)-(D) instead of [substrate (A)]-(B)-(C)-(D), when no planarization layer is applied.

Preferably the planarization layer (P) is made by depositing the material making up the planarization layer on the substrate before applying the MLBF. In the case that the planarization layer is organic polymer-based, which is preferred, the planarization layer can be formed by applying a liquid organic coating composition on the substrate and then curing the thus formed layer, for example by heating or by radiation such as UV radiation. UV radiation is preferred. More preferably the liquid organic coating compositions used to produce the planarization layer fall under the same definition as the liquid radiation-curable coating composition C used to form the transparent radiation-cured (meth)acrylate layer (C). In such case (P) can be identical with (C). In such case both layers (C) of the MLBF can be identical or different from each other as long as they fall under the definition of (C).

Transparent, at least Partially Inorganic Barrier Layer (B)

The transparent, at least partially inorganic barrier layer(s) (B) serve to provide a good moisture barrier property to the MLBF. The water vapor transmission rate (WVTR) at 40° C. and 90% relative humidity should preferably be lower than 10-3 g/m²/day, even more preferred less than 5*10-4 g/m²/day.

As defined above, the term “at least partially inorganic” in view of the “at least partially inorganic barrier layer(s) (B)” means that the layer or layers may be completely composed of inorganic material, but may also be composed of inorganic layers and organic layers, preferably in an alternating order.

In case layer (B) consists of one or more inorganic layers, layer (B) is denoted in the following as (Bⁱ)ₘ, wherein “i” stands for “inorganic” and m for the number of layers. Preferably m being from 1 to 2000, more preferred m=10 to 1000 and most preferred m=20 to 500.

In case layer (B) further contains one or more organic layers beside the one or more inorganic layers, layer (B) is denoted in the following as (BⁱB^{o})ₙ(Bⁱ)ₜ, wherein “i” stands for “inorganic”, “o” stands for “organic”; n for the number of (BⁱB^{o}) repetition layers and t for 1 or 0. The first layer of the barrier layer deposited on substrate (A) or the optional planarization layer (P) is always an inorganic layer Bⁱ, but the last layer in such stack can be either an inorganic layer (t=1) or an organic layer (t=0). The presence of such organic layers between the inorganic layers provides the barrier with additional flexibility, particularly if the MLBF has a thickness of more than 50 nm.

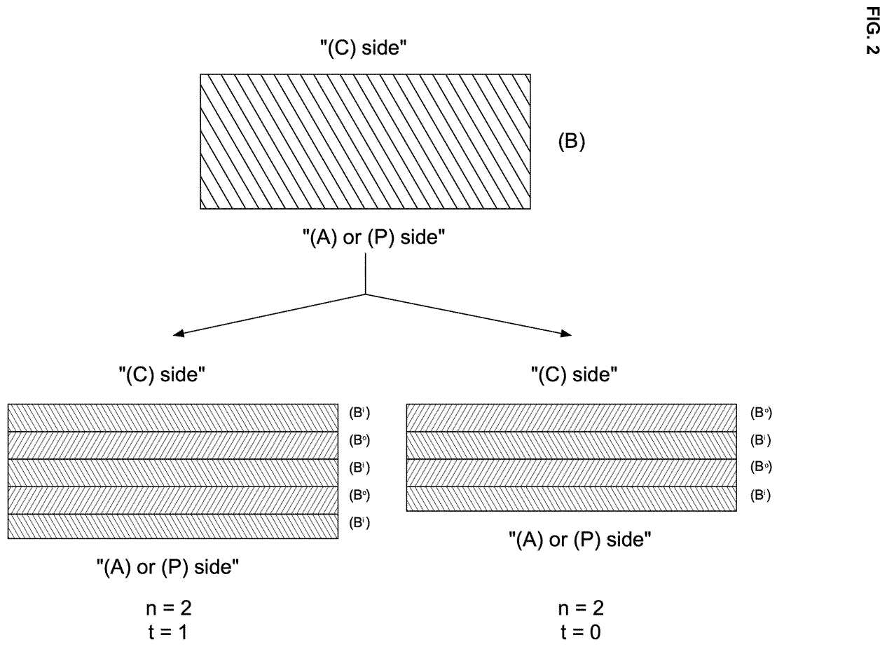

FIG. 2 shows a possible “micro-architecture” of layer (B), in case layer (B) consist of a layer stack (BⁱB^{o})ₙ(Bⁱ)ₜ with n=2 and t=1 and 0, respectively.

The mandatory presence of the inorganic layer(s) (Bⁱ) in the at least partially inorganic barrier layer (B) is responsible for the winding ability and flexibility of the overall MLBF without the risk to compromise on water vapor transmission rate.

The deposition of the inorganic layer(s) (Bⁱ) can be achieved by several different techniques as e.g., Chemical Vapor Deposition (CVD), Physical Vapor Deposition (PVD), Atomic Layer Deposition (ALD) and/or sputtering, while the deposition of the organic layer(s) (B^{o}) can e.g., be achieved by Chemical Vapor Deposition (CVD), Molecular Layer Deposition (MLD), Organic (Thermal or Electron Beam) Evaporation, Wet Coating Deposition. Techniques like PVD, CVD and sputtering to get the inorganic layer are known to one of skill in the art and e.g., described in US 2013/0034689 A1 and EP 2 692 520 A1.

The inorganic material used to form the one or more inorganic layers is selected from the group consisting of metal oxides, metal nitrides, metal oxynitrides, and combinations thereof.

Most preferred inorganic materials to form the inorganic layer are metal oxides, particularly the metal oxides of aluminum, titanium, silicon, zinc, zirconium, hafnium, indium, tin, indium-tin, tantalium and calcium, of which aluminium, silicon and titanium are the preferred oxide elements. In any of the embodiments described herein, the use of metal oxides as inorganic material to form the inorganic layer(s) is particularly preferred.

It is further possible to use metal nitrides as inorganic material. Amongst the metal nitrides, the group of metal nitrides consisting of aluminum nitride, silicon nitride and boron nitride is preferred. The formation of a metal nitride layer as inorganic layer (Bⁱ) on the substrate (A) and/or planarization layer (P) is preferably achieved by PE (Plasma Enhanced)-CVD, CVD, ALD, or sputtering. Suitable techniques are e.g., described in WO2011028119. In particular, it is shown in literature (W. Manders et al., AIMCAL R2R Conference, Florida 2017) that a thin silicon nitride barrier layer fabricated by PE-CVD on a PET substrate has a WVTR of 5*10⁻⁴ g/m²/day.

Moreover, it is possible to use metal oxynitrides as inorganic material. Amongst the metal oxynitrides, the group of metal oxynitrides consisting of aluminum oxynitride, silicon oxynitride and boron oxynitride is preferred. The formation of a metal oxynitride layer as inorganic layer (Bⁱ) on the substrate (A) and/or planarization layer (P) is preferably achieved by PE (Plasma Enhanced)-CVD, CVD, ALD, or sputtering. Suitable techniques are e.g., described in CN 1899815 B.

Within an inorganic layer (Bⁱ), combinations of the above-mentioned inorganic material can be used. Moreover, in a stack of inorganic layers such as (Bⁱ)ₘeach of the inorganic layers (Bⁱ) may be independently chosen from the above inorganic materials and the same applies to a layer stack such as (BⁱB^{o})ₙ(Bⁱ)ₜ, the values of m, n and t are those as described herein above.

Preferably the layer thickness of the one or more at least partially inorganic barrier layer (B) is in total in the range from 10 to 1000 nm, more preferred in the range from 20 to 500 nm and most preferred in the range from 30 to 200 nm.

Preferred, amongst the afore-mentioned techniques for deposition of the inorganic layer(s) (Bⁱ), preferably the metal oxide layers (Bⁱ) are ALD, in case (B) is (Bⁱ)ₘ; and ALD combined with MLD, in case of (B) is (BⁱB^{o})ₙ(Bⁱ)ₜ.

The use of the ALD technique for the preparation of transparent barrier layer (Bⁱ) is preferred, since it is possible by using ALD to step-wise form chemically-bound nanolaminate self-limiting layers with excellent thickness control that are highly conformal, well order and dense each with a defined thickness. Such method, particularly to produce metal oxide layers (Bⁱ), is e.g., disclosed in WO 2011/099858 A1, but is also part of the combined ALD/MLD techniques as e.g., disclosed WO 2015/188990 A2 and WO 2015/188992 A1.

Even more preferred the transparent barrier layer is (BⁱB^{o})ₙ(Bⁱ)ₜ, wherein the layer(s) (Bⁱ) are obtained by ALD and the layers (B^{o}) are prepared by MLD. Combining ALD with the MLD technique allows the alternating deposition at molecular level (few nanometer thick) of organic flexiblizing layers that are deposited with covalent chemical linkage to the inorganic material as e.g., disclosed in WO 2015/188990 A2 and WO 2015/188992 A1.

The organic molecules used in the MLD technique to obtain a layer (B^{o}) have special functional groups able to be chemically-bound to the inorganic layer (Bⁱ) such as thiol, disulfide, sulfide, selenol, amine, carboxylate, phosphate or phosphonate, or derivatives thereof, as e.g., described in WO 2015/030297 A1, WO 2015/188990 A2 and WO 2015/188992 A1.

Most preferred organic molecules to produce layer (B^{o}) belong to the family of aromatic thiols, as e.g., mercaptobenzoic acid, mercaptophenol, amino mercaptophenol and the like. The scope of this organic molecular layer is to give to the brittle inorganic oxide barrier the flexibility and bendability required in roll-to-roll processing, also known as web processing, reel-to-reel processing or R2R, which is a process of creating electronic devices on a roll of flexible plastic.

Some more details on the manufacture of the transparent, at least partially inorganic barrier layer(s) (B) are described herein below under the section describing the method for producing the MLBF of the invention.

### Transparent Radiation-Cured (Meth)acrylate Layer (C)

As stated above, the term “radiation-cured” in view of the one or more transparent radiation-cured (meth)acrylate layers (C) refers to the radiation-curable nature of crosslinkable monomers, oligomers and polymers being used to produce the radiation-cured (meth)acrylate layers, i.e., the presence of (meth)acrylic groups on the afore-mentioned species before curing, i.e., crosslinking, which react with each other to form the radiation-cured (meth)acrylate layer. While the term “(meth)acrylate” denotes for both “acrylate” and “methacrylate”, it preferably denotes for “acrylate”. The same applies for the use of terms “(meth)acryl” and “(meth)acrylic”.

Thus, radiation curing is typically achieved by actinic radiation, such as electron beam (EB) or UV radiation. Curing by UV-radiation is particularly preferred.

Therefore, the transparent radiation-cured (meth)acrylate layer(s) (C) are preferably based on UV-cured solvent-free (meth)acrylic system. The term “solvent-free” means free of non-reactive solvent, since reactive diluents are not excluded by this term.

Preferably, the coating material used to produce the transparent radiation-cured (meth)acrylate layer(s) (C) has a viscosity at 25° C. determined by Capillary Viscometers or Rotational Rheometer before curing of less than 500 mPas, most preferably less than 300 mPas.

Species used to form the one or more transparent radiation-cured (meth)acrylate layers (C) preferably comprise
i. one or more radiation-curable oligomeric (meth)acrylate-functional species;
ii. one or more radiation curable (meth)acrylate-functional monomers;
iii one or more adhesion promoters;
iv. in case of UV-curing, one or more photoinitiators;
V. one or more compounds selected from UV absorbers, light stabilizers and antioxidants; and
vi. optionally one or more coatings additives.

### Radiation-Curable Oligomeric (Meth)Acrylate-Functional Species i.

The one or more radiation-curable oligomeric (meth)acrylate-functional species are preferably selected from the group consisting of polyester (meth)acrylates, epoxy (meth)acrylates, aliphatic and/or aromatic urethane (meth)acrylates, preferably aliphatic urethane (meth)acrylates, polyether (meth)acrylates and (meth)acrylated poly(meth)acrylates, amongst which the urethane (meth)acrylates, epoxy (meth)acrylates and polyether (meth)acrylates are preferred.

Typically, the radiation-curable oligomeric (meth)acrylate-functional species have a viscosity at 25° C. above 70 mPas.

Polyester (meth)acrylates typically have a lower viscosity compared to the other olilgomers, while epoxy (meth)acrylates have an increased reactivity and the coatings obtained by their use show a good hardness and chemical resistance. (Meth)acrylated poly(meth)acrylates are known for their good adhesion. Aromatic urethane (meth)acrylates provide an increased flexibility, elongation and toughness, a good hardness and chemical resistance to the coatings obtained therewith and multifunctional aromatic urethane (meth)acrylates show an increased reactivity. Aliphatic urethane (meth)acrylates show the same good characteristics as the aromatic urethane (meth)acrylates, but tend less to undesired yellowing.

The total amount of the one or more radiation-curable oligomeric (meth)acrylate-functional species preferably ranges from 5 wt.-% to 30 wt.-% most preferably from 5 wt.-% to 20 wt.-% and even more preferred from 5 wt.-% to 15 wt.-% based on the total weight of the radiation-curable coating composition C.

Radiation-Curable (Meth)acrylate-functional Monomers ii.

The one or more radiation curable (meth)acrylate-functional monomers are those known to one of skill in the art of radiation-curable compositions. Such radiation curable (meth)acrylate-functional monomers possess low viscosities, preferably viscosities at 25° C. from 1 to 50 mPas, more preferred from 2 to 40 mPas or even 2 to 30 mPas. They are used to dilute the radiation-curable oligomeric (meth)acrylate-functional species and are thus also known as radiation-curable reactive diluents, since they act as solvents, but remain in the cured coating after curing. Such monomers may, in some cases, contain dialkyleneglycol or trialkyleneglycol groups, but are still considered herein as monomers due to their definite molecular weight and viscosity below 50 mPas at 25° C.

The (meth)acrylate-functional monomers as preferably used herein preferably possess a hydrophobic backbone and provide an excellent adhesion to plastic and metal substrates, good chemical and water resistance, flexibility to the radiation-cured coating layers containing these and they show low release of volatile organic compounds.

The one or more (meth)acrylate-functional monomers comprise mono(meth)acrylate functional monomers, di(meth)acrylate functional monomers and tri-, tetra-, penta- and hexa(meth)acrylate functional monomers, amongst which the mono(meth)acrylate functional monomers and di(meth)acrylate functional monomers are most preferred.

Examples of mono(meth)acrylate functional monomers include hydrocarbylesters of (meth)acrylic acid, wherein the hydrocarbyl residues can be aliphatic or aromatic and linear, branched or cyclic, preferably the hydrocarbyl groups containing 4 to 20, more preferably 6 to 18 carbon atoms. Specific examples e.g., alkyl(meth)acrylates, such as cyclohexyl(meth)acrylate, hexyl(meth)acrylate, 2-ethylhexyl(meth)acrylate, tert-octyl (meth)acrylate, decyl(meth)acrylate, isodecyl(meth)acrylate, lauryl(meth)acrylate, stearyl(meth)acrylate, isostearyl(meth)acrylate, 4-n-butylcyclohexyl(meth)acrylate; bornyl(meth)acrylate; isobornyl(meth)acrylate; e.g., aralkyl(meth)acrylates, such as benzyl(meth)acrylate; e.g., aryl(meth)acrylates such as 4-butylphenyl(meth)acrylate, phenyl (meth)acrylate and 2,3,4,5-tetramethylphenyl (meth)acrylate. Further examples of mono(meth)acrylate functional monomers include ether oxygen containing hydrocarbylesters of (meth)acrylic acid, wherein the ether oxygen containing hydrocarbyl residues can be aliphatic or aromatic and linear, branched or cyclic, preferably the ether oxygen containing hydrocarbyl groups contain 4 to 20, more preferably 6 to 18 carbon atoms. Specific examples are e.g., alkoxyalkyl(meth)acrylates, such as, butoxyethyl(meth)acrylate, butoxymethyl(meth)acrylate, 3-methoxybutyl(meth)acrylate; aryloxyalkyl(meth)acrylates, such as phenoxymethyl (meth)acrylate and phenoxyethyl(meth)acrylate; 2-ethylhexyl diglycol (meth)acrylate, 2-(2-methoxyethoxy)ethyl(meth)acrylate, 2-(2-butoxyethoxy)ethyl(meth)acrylate; and trimethylolpropanformal (meth)acrylate.

Examples of di(meth)acrylate functional monomers are alkanediol di(meth)acrylates, wherein the alkanediol preferably contains 3 to 16, more preferred 4 to 14 carbon atoms. Specific examples are 1,3-propanediol di(meth)acrylate, 1,3-butanediol di(meth)acrylate, 1,4-butanediol di(meth)acrylate, 1,5-pentanediol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, 1,12-dodecanediol di(meth)acrylate and 1,14-tetradecanediol di(meth)acrylate. Further examples of di(meth)acrylate functional monomers are dialkyleneglycol di(meth)acrylates, such as diethylenglycol di(meth)acrylate and dipropylenglycol di(meth)acrylate; trialkyleneglycol (meth)acrylates, such as triethylenglycol (meth)acrylate and tripropylenglycol di(meth)acrylate; and neopentylglycol-propoxy di(meth)acrylate.

Less preferred are the following tri- to hexa(meth)acrylate functional monomers. The higher the functionality, the less preferred are the monomers in the present invention.

Specific examples of tri(meth)acrylate functional monomers include trimethylolpropane tri(meth)acrylate, trimethylolethane tri(meth)acrylate, pentaerythritol tri(meth)acrylate, dipentaerythritol tri(meth)acrylate, trimethylolpropane tris((meth)acryloyloxypropyl)-ether, dipentaerythritol propionate tri(meth)acrylate, tris((meth)acryloyloxyethyl) isocyanurate,

Specific examples of tetra(meth)acrylate-functional monomers include pentaerythritol tetra(meth)acrylate, ditrimethylolpropane tetra(meth)acrylate, dipentaerythritol propionate tetra(meth)acrylate, and ethoxylated pentaerythritol tetra(meth)acrylate.

Specific examples of penta(meth)acrylate-functional monomers include dipentaerythritol penta(meth)acrylate.

Specific examples of hexa(meth)acrylate-functional monomers include, e.g., dipentaerythritol hexa(meth)acrylate.

Preferably, the radiation-curable compositions of the present invention comprise from the groups of radiation curable (meth)acrylate-functional monomers ii. only mono(meth)acrylic monomers.

The total amount of the one or more radiation-curable (meth)acrylate-functional monomers preferably ranges from 10 wt.-% to 90 wt.-% most preferably from 15 wt.-% to 85 wt.-% and even more preferred from 20 wt.-% to 80 wt.-% based on the total weight of the radiation-curable coating composition.

### Adhesion Promoters iii.

The one or more adhesion promoters are preferably selected from the group consisting of functionalized trialkoxysilanes and functionalized dialkoxyalkylsilanes, preferably functionalized trialkoxysilanes, such as functionalized trimethoxysilanes, the functional groups preferably being selected from thiol groups, (meth)acryl groups, amino groups and epoxy groups; and (meth)acrylated phosphoric acid esters.

The total amount of the one or more adhesion promoters iii. preferably ranges from 0.5 wt.-% to 10 wt.-% most preferably from 1 wt.-% to 8 wt.-% and even more preferred from 1.5 wt.-% to 7 wt.-% based on the total weight of the radiation-curable coating composition.

### Photoinitiators iv.

In case of UV-curing one or more photoinitiators, preferably selected from the group consisting of alpha-cleaving photoinitiators, such as alpha-hydroxyketones (e.g., benzoin, acetophenones), alpha-alkoxyketones (e.g., benzoinethers, benzilketales), alpha-aminoketones and acyl phosphine oxides are contained.

The photoinitiators can be subsumed under the terms “surface curing types”, such as alpha-alkoxyketones and “bulk curing types”, such as acyl phosphine oxides. If both are present, it is preferred that the photoinitiator weight ratio between surface curing types and bulk curing types ranges from 1:4 to 1:1.

The total amount of the one or more photoinitiators iv., if contained, preferably ranges from 0.5 wt.-% to 6 wt.-% most preferably from 2 wt.-% to 5 wt.-% and even more preferred from 3 wt.-% to 4 wt.-% based on the total weight of the radiation-curable coating composition.

### UV Absorbers, Light Stabilizers, Antioxidants v.

The UV absorbers are preferably selected from the group consisting of 2-(2′-hydroxyphenyl)benzotriazoles, 2-hydroxybenzophenones, esters of substituted and unsubstituted benzoic acids, acrylates s like ethyl alpha-cyano-beta, beta-diphenylacrylates, 2-(2-hydroxyphenyl)-1,3,5-triazines and oxamides.

The total amount of the one or more UV absorbers v. preferably ranges from 1 wt.-% to 5 wt.-%, more preferred from 1.5 to 3.5 wt.-% based on the total weight of the radiation-curable coating composition.

The light stabilizers v. are preferably hindered amine light stabilizers (HALS) including NOR-HALS. The NOR-HALS is a sub class of HALS also called Aminoxyl radical hindered amine light stabilizers. While HALS act as a base and become neutralized by acid for example hydrochloric acid, NOR-HALS, are not a strong base and are not deactivated by hydrochloric acid.

The total amount of the one or more light stabilizers v. preferably ranges from 0.2 wt.-% to 4 wt.-%, more preferred from 0.5 to 3 wt.-% and most preferred from 0.8 to 2 wt.-% based on the total weight of the radiation-curable coating composition.

The antioxidants v. are preferably tert-butyl hindered phenols and serve to improve long-time weatherability and thermal resistance.

The total amount of the one or more antioxidants v. preferably ranges from 0.1 wt.-% to 2 wt.-%, more preferred from 0.2 to 1 wt.-% based on the total weight of the radiation-curable coating composition.

### Coatings Additives vi.

The coating compositions C may contain typical coatings additives, such as levelling agent, defoamers, preferably, but not necessarily are reactive in radiation-curing.

### Thickness of the Transparent Radiation-Cured (Meth)Acrylate Layer (C)

The final thickness of the transparent, radiation-cured (meth)acrylate layer (C) preferably ranges from 1 to 100 μm, more preferred from 1 to 50 μm and most preferred from 5 to 30 μm. The coating material applied to form the transparent radiation-cured (meth)acrylate layer(s) (C) can be applied by standard wet coating methods.

### Transparent, Thermally-cured Coating Layer (D)

The transparent, thermally-cured coating layer (D) is preferably a transparent, thermally-cured polyurethane coating layer (D).

The transparent, thermally-cured coating layer (D) is characterized by an excellent adhesion to the underneath transparent, radiation-cured (meth)acrylate layer (C) both before and after prolongated aging at elevated and lower temperature and under high humidity conditions.

From the viewpoint of light stability, flexibility, resistance to moisture, chemical and temperature stability the use of hydroxy-functionalized partially fluorinated reactive polymers are preferred also considering their fast reactivity with different types of hardeners. It is preferred that the transparent, thermally-cured coating layer (D) is a polyurethane layer, preferably formed by reacting at least one hydroxyl-functional polymer, selected from radically polymerized, hydroxyl-functional fluoropolymers and hydroxy-functional poly(meth)acrylates, with a crosslinker, preferably one or more polyisocyanates, even more preferred one or more hydrophobic polyisocyanates.

### Hydroxyl-Functional Polymers Formed by Radical Polymerization

The hydroxyl-functional polymers formed by radical polymerization and preferably to be used in the preparation of the transparent, thermally-cured coating layer (D) are preferably selected from the groups of radically polymerized hydroxyl-functional fluor-containing polymers (“hydroxy-functional fluoropolymers”) and hydroxy-functional poly(meth)acrylates. The term “polymer” as used in this context includes “copolymers” and the term “copolymer” includes any polymer containing at least two different monomeric units.

Preferably, the radically polymerized, hydroxyl-functional fluoropolymers contain repeating units formed by polymerizing preferably one or more ethylenically unsaturated fluor containing monomers selected from the group consisting of vinylfluoride FCH═CH₂, vinylidenfluoride F₂C═CH₂, tetrafluorethylene F₂C═CF₂, F₂C═CF(OCF₃), F₂C═CF(CF₃) and hexafluoropropylene, and mixtures thereof.

Other preferred monomers that may be used in combination with the fluor containing monomers described above are for example ethylene, propylene, n-butene, isobutene, vinyl benzoate and vinyl ethers, such as H₂C═CH—O—R or H₂C═CH—CH₂—O—R, with R being a linear, cyclic and/or branched hydrocarbyl group, such as an alkyl or cycloalkyl group. Such groups R preferably containing from 1 to 20, more preferably 2 to 16, such as 4 to 12 carbon atoms.

Since the fluoropolymers contain hydroxyl groups, ethylenically unsaturated hydroxyl-functional monomers also need to be employed in the radical polymerization of the radically polymerized hydroxyl-functional fluoropolymers. Examples of hydroxyl-functional monomers are hydroxyl-functional vinyl ethers such as 2-hydroxyethyl vinyl ether, 3-hydroxypropyl vinyl ether, 2-hydroxy-2-methylpropyl vinyl ether, 4-hydroxybutyl vinyl ether, 4-hydroxy-2-methylbutyl vinyl ether, 5-hydroxypentyl vinyl ether and 6-hydroxyhexyl vinyl ether; hydroxyl-functional allyl ethers such as 2-hydroxyethyl allyl ether, 4-hydroxybutyl allyl ether and glycerol monoallyl ether; or hydroxyalkyl esters of (meth)acrylic acids such as 2-hydroxyethyl acrylate and 2-hydroxy-ethyl methacrylate. Among these, hydroxyl-containing vinyl ethers, especially 4-hydroxybutyl vinyl ether and 2-hydroxyethyl vinyl ether are particularly preferred.

Alternatively, ethylenically unsaturated monomers which can be modified in a post-polymerization step to exhibit a hydroxyl group. Such monomers may e.g., be selected from the group of vinyl ethers or ester such as H₂C═CH—O—(C═O)ₘR with R being an alkyl group and m=0 or 1, and hydrolysing such groups after polymerization to obtain residues —CH—CH(OH)— in the polymer chain.

As the proportion of fluor containing monomers in the fluoropolymer becomes larger, the weatherability of the coated film will improve. On the other hand, when it becomes smaller, the solubility of the fluoropolymer will improve. The proportion of fluor containing monomer relative to the total monomer amount is preferably between 30 to 70 mol %, more preferably between 40 and 60 mol %.

The hydroxyl group content of the fluoropolymer is preferably from 30 to 200 mg KOH/g, more preferably from 40 to 150 mg KOH/g.

Preferably, the fluorine content of the fluoropolymers ranges from 5 wt.-% to 35 wt.-%, more preferred from 10 wt.-% to 35 wt.-%, based on the weight of the polymer.

Radically polymerized, hydroxyl-functional fluoropolymers are e.g., commercially available as Zeffle® GK polymers from Daikin Industries and as LUMIFLON® polymers from Asahi Glass.

Instead of or in combination with the afore-mentioned radically polymerized hydroxyl-functional fluoropolymers, hydroxy-functional poly(meth)acrylates can be used to form the transparent, thermally cured polyurethane coating layer (D).

Such hydroxy-functional poly(meth)acrylates preferably comprise, beside hydroxy-functional (meth)acrylates, like hydroxyalkyl(meth)acrylates, such es hydroxyethyl(meth)acrylate, hydroxypropyl (meth)acrylate and hydroxybutyl(meth)acrylate; alkyl(meth)acrylates, the alkyl group preferably having 1 to 8 carbon atoms; styrene; and (meth)acrylic acid and their acid functional derivatives. Preferred monomers of the latter kind contained in the hydroxy-functional poly(meth)acrylates include but are not limited to (meth)acrylic acid; 2-alkyl (meth)acrylic acids, the alkyl having 2 to 8, preferably 2 to 6 carbon atoms, such as in 2-ethyl (meth)acrylic acid, 2-propyl (meth)acrylic acid, 2-butyl (meth)acrylic acid and 2-hexamethyl (meth)acrylic acid; halogenated alkyl (meth)acrylic acid, such as 2-(trifluoromethyl) (meth)acrylic acid; and halogenated (meth)acrylic acids, such as 2-bromo (meth)acrylic acid; and salts of the afore-mentioned acids, preferably alkaline metal salts, such as sodium and potassium salts, or zinc salts.

Preferably, the hydroxy-functional poly(meth)acrylates have a hydroxyl number from 50 to 200 mg KOH/g, more preferred 60 to 160 mg KOH/g, even more preferred 70 to 150 mg KOH/g.

Preferably, the hydroxy-functional poly(meth)acrylates have a number-average molecular weight from 5,000 to 50,000 g/mol, more preferred 10,000 to 40,000 g/mol, even more preferred 12,000 to 30,000 g/mol, as determined by gas permeation chromatography using a styrene standard.

The radically polymerized hydroxyl-functional fluoropolymers and the hydroxyl-functional poly(meth)acrylates can be used alone or blended with each other. A preferred blending ratio can range from 90:10 wt.-% to 10:90 wt.-% and most preferably from 70:30 wt.-% and 30:70 wt.-% depending on required performance.

Particularly with respect to the adhesion on the transparent radiation-cured (meth)acrylate layer (C), it was surprisingly found that the use of the radically polymerized hydroxyl-functional fluoropolymers is preferred, if used alone, or in combination with the hydroxy-functional poly(meth)acrylates, most preferred, if used alone.

### Polyisocyanates

To form the transparent, thermally-cured coating layer (D), preferably the transparent, thermally-cured polyurethane coating layer (D) the afore-described hydroxyl-functional polymers need to be crosslinked. Crosslinking of these polymers is preferably achieved by crosslinking agents, such as polyisocyanates.

In the context of the present invention the term “polyisocyanate” stands for compounds containing at least two free, i.e., non-blocked, isocyanate groups. Thus, the term polyisocyanates e.g., encompasses diisocyanates and triisocyanates, but also oligomers of such diisocyanates and triisocyanates, e.g., dimers and trimers of such diisocyanates and triisocyanates.

If the term “hydrophobic” is used in conjunction with the term “polyisocyanate”, this term describes that the polyisocyanate does typically not contain hydrophilic groups as particularly, charged groups or polyethyleneoxide groups, but rather contains only hydrocarbyl groups, besides the isocyanate groups themselves and groups obtained by oligomerization of isocyanate groups.

Most preferred the polyisocyanates are hydrophobic polyisocyanates.

The polyisocyanates used in the formation of the transparent, thermally-cured polyurethane coating layer (D) are selected from the group consisting of aliphatic including alicyclic polyisocyanates, araliphatic polyisocyanates and aromatic polyisocyanates. Oligomers of diisocyanates and triisocyanates may be formed from the same diisocyanate or triisocyanate, but also from mixtures of these.

Examples of aliphatic diisocyanates are, e.g., 1,4-tetramethylene diisocyanate, ethyl(2,6-diisocyanato) hexanoate, 1,6-hexamethylene diisocyanate, 1,12-dodecamethylene diisocyanate, 2,2,4- or 2,4,4-trimethylhexamethylene diisocyanate; aliphatic triisocyanates are e.g., 1,3,6-hexamethylene triisocyanate, 1,8-diisocyanato-4-isocyanatomethyloctane, or 2-isocyanatoethyl(2,6-diisocyanato) hexanoate; alicyclic diisocyanates are e.g., 1,3- or 1,4-bis(isocyanatomethylcyclohexane), dicyclo methane-4,4′-diisocyanate, 1,3- or 1,4-diisocyanato-cyclohexane, 3,5,5-trimethyl(3-isocyanato-3-methyl)cyclohexyl isocyanate, dicyclo-hexylmethane-4,4′-diisocyanate, or 2,5- or 2,6-diisocyanatomethylnorbornane; and alicyclic triisocyanates are e.g. 2,5-or 2,6-diisocyanatomethyl-2-isocyanato propyl-norbornane.

Examples of araliphatic polyisocyanates are e.g., aralkylene diisocyanates such as m-xylylene diisocyanate or a, a, a′, a′-tetramethyl-m-xylylene diisocyanate.

Examples of aromatic diisocyanates are e.g., m- or p-phenylene diisocyanate, tolylene-2,4- or 2,6-diisocyanate, diphenylmethane-4,4′-diisocyanate, naphthalene-1,5-diisocyanate, diphenyl-4,4′-diisocyanate, 4,4′-diisocyanato-3,3′-dimethyldiphenyl, 3-methyl-diphenylmethane-4,4′-diisocyanate, or diphenyl ether-4,4′-diisocyanate; aromatic triisocyanates are e.g., triphenylmethane triisocyanate or tris(isocyanatophenyl)-thiophosphate.

Oligomeric polyisocyanates are e.g., diisocyanates or polyisocyanates having an uretdione structure obtained by cyclodimerization of isocyanate groups of various diisocyanates and triisocyanates described above; polyisocyanates having an isocyanurate structure or an iminooxadiazinedione structure obtained by cyclotrimerization of isocyanate groups of various diisocyanates and triisocyanates described above; polyisocyanates having a biuret structure obtained by reacting various diisocyanates or triisocyanates described above with water; polyisocyanates having an oxadiazinetrione structure obtained by reacting various diisocyanates or triisocyanates with carbon dioxide; and polyisocyanates having an allophanate structure.

Preferred polyisocyanates are aliphatic or alicyclic di- or triisocyanates, aralkylene diisocyanates, or oligomers derived therefrom, in view of the stability of isocyanate groups in water and the weather resistance of a cured layer containing such polyisocyanates.

Highly preferred polyisocyanates are polyisocyanates having three or more functionalities such as isocyanurate type or iminooxadiazinedione type polyisocyanate, polyisocyanate having a biuret structure, polyisocyanate having an uretdione structure, polyisocyanate having an allophanate structure, or polyisocyanates obtained by reacting diisocyanate with polyhydric alcohol having three or more functionalities. The core of the polyisocyanate preferably includes an aliphatic polyisocyanate or a trimer derived therefrom.

It has been observed that aromatic polyisocyanates may result in more yellowing of the layer upon storage under warm and humid conditions or after extensive exposure to UV radiation. Thus, aliphatic polyisocyanates are preferred in the present invention.

Particularly preferred polyisocyanate compounds include hexamethylene diisocyanate (HDI), isocyanurate trimer or iminooxadiazinedione trimers derived therefrom, isophorone diisocyanate (IPDI) and IPDI-based isocyanurate or iminooxadiazinedione; and dicyclohexylmethane diisocyanate (H12MDI) and H12MDI-based isocyanurate or iminooxadiazinedione. The isocyanurates or iminooxadiazinediones of the afore-mentioned diisocyanates being preferred.

The transparent, thermally-cured coating layer (D) may further contain additives like UV-absorbers, light stabilizers and antioxidant, which can be the same as described for the transparent, radiation-cured (meth)acrylate layer (C) to improve weatherability performance and lifetime by increasing UV and heat stability. The UV-absorbers, light stabilizers and antioxidant are preferably present in the same amount ranges as described above for the transparent, radiation-cured (meth)acrylate layer (C).

The transparent, thermally-cured coating layer (D) is characterized by a glass transition temperature of preferably more than 10° C., more preferably of more than 50° C., but preferably less than 100° C.

The final thickness of the transparent, thermally-cured coating layer (D) is preferably in the range from 10 μm to 100 μm, more preferred in the range from 20 μm and 80 μm and most preferred in the range from 25 μm to 60 μm.

### Specific Embodiments of the MLBF and the MLBF Coated Substrate

In one embodiment the MLBF architecture on the substrate is as follows:

[substrate(A)]-(B)-(C)-(D).

In this embodiment layer (B) can be layer (Bⁱ) or layer (BⁱB^{o})ₙ(Bⁱ)ₜ, wherein all definitions are as above. FIG. 1 shows this embodiment, when optional planarization layer (P) in FIG. 1 is omitted. FIG. 2 shows the possible micro-architectures of (B), namely being (BⁱB^{o})ₙ(Bⁱ)ₜ, whereas in FIG. 2 n=2 and t=1 and 0, respectively.

In a further embodiment the MLBF architecture on the substrate is as follows:

[substrate(A)]-(P)-(B)-(C)-(D).

In this embodiment layer (B) can be layer (Bⁱ) or layer (BⁱB^{o})ₙ(Bⁱ)ₜ, wherein all definitions are as above; and layer (P) can be the same as layer (C), wherein all definitions are as above and both layers (C) can be same or different. FIG. 1 shows this embodiment, when optional planarization layer (P) in FIG. 1 is present. FIG. 2 shows the possible micro-architectures of (B), namely being (BⁱB^{o})ₙ(Bⁱ)ₜ, whereas in FIG. 2 n=2 and t=1 and 0, respectively.

In yet another embodiment the MLBF architecture on the substrate is as follows:

[substrate(A)]-[(B)-(C)]ₐ-(D).

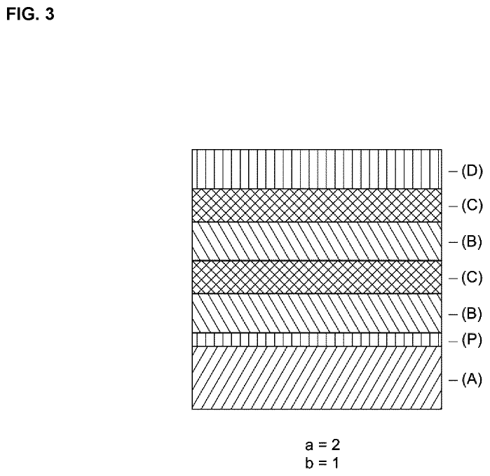

In this embodiment layer (B) can be layer (Bⁱ) or layer (BⁱB^{o})ₙ(Bⁱ)ₜ, wherein all definitions are as above; and the sequence of [(B)-(C)] can be repeated a-times, a being an integer from 1 to 10. In case a ≥2, the a layers (B) can be the same or different and the a layers (C) can be the same or different. This embodiment is shown in FIG. 3 with a=2 and if in FIG. 3 b would be 0. FIG. 2 again shows the possible micro-architectures of (B), namely being (BⁱB^{o})ₙ(Bⁱ)ₜ, whereas in FIG. 2 n=2 and t=1 and 0, respectively.

In a general embodiment the MLBF architecture on the substrate is as follows:

[substrate(A)]-(P)_{b}-[(B)-(C)]ₐ-(D).

In this embodiment layer (B) can be layer (Bⁱ) or layer (BⁱB^{o})ₙ(Bⁱ)ₜ, wherein all definitions are as above; and the sequence of layers [(B)-(C)] can be repeated a-times, a being an integer from 1 to 10. In case a ≥2, the a layers (B) can be the same or different and the a layers (C) can be the same or different; and b=0 or 1. Thus a planarization layer might be present (b=1) or not (b=0). This embodiment is shown in FIG. 3 with a=2 and p=1. In this general embodiment, as well as in all specific embodiments shown in the specification, at least one layer (C) is in direct contact with one layer (D).

All of the afore-mentioned MLBF architectures have in common that the sequence of layers, starting from the [substrate (A)] is (B)-(C)-(D), irrespective of the fact that this sequence may preceded by a planarization layer (P) between the substrate and the first layer (B); or that the sequence might be interrupted by further sequences such as one or more additional sequences of [(B)-(C)] after the first sequence of [(B)-(C)]; or that the sequence might be interrupted by further layers between layer (B) and layer (C) and/or layer (C) and layer (D).

Preferable layer (D) is directly on top of layer (C), which is preferably directly on top of layer (B), thus all three mandatory layers of the MLBF are in direct contact, i.e., there are no layers between the three mandatory layers.

The afore-mentioned architectures are chosen in dependence of the application requirements, the desired level of moisture barrier (WVTR) and the desired type of polymeric film substrate. E.g., repeating layers (B) and (C) will typically provide an improved moisture barrier, since more than one layer (B) is present, while polymeric films as a substrate may require a planarization layer (P), if the substrate has surface irregularities. If the application field requires a more flexible MLBF, layer (B) might have the structure (BⁱB^{o})ₙ(Bⁱ)ₜ, etc.

For all of the afore-mentioned embodiments it is preferred that the substrate is a polymeric substrate, even more preferred a transparent, polymeric substrate.

### Characteristics of the MLBF of the Invention

The MLBF of the invention typically has an excellent prolongated thermal stability of at least 2000 h at 85° C. and 85% relative humidity without self-delamination or formation of cracks. The yellow Index (YI) increase after extensive climate aging is typically less than <10, particularly, if aliphatic monomers and oligomers are used in the production of transparent, radiation-cured (meth)acrylate layer (C) and the transparent, thermally-cured coating layer (D).

This MLBF of the invention also shows good UV stability with an estimated outdoor lifetime of more than 20 years, which can be estimated in UV accelerated metal halide irradiation testing carried out for at least 400 h, and even up to more than 800 h resulting in a variation in transmittance of less than 5% in the wavelength range of light from 400 to 1100 nm.

### Method of Producing a Multilayer Barrier Film and Method of Producing a Thus Coated Substrate

The invention provides a method for producing a multilayer barrier film comprising the at least the steps of
a. providing a substrate;
b. applying one or more inorganic layers on the substrate by one or more methods selected from chemical vapor deposition (CVD), physical vapor deposition (PVD), atomic layer deposition (ALD) and sputtering to form one or more transparent, at least partially inorganic barrier layers (B); and
c. applying one or more radiation-curable (meth)acrylic coating compositions C on the one or more transparent, at least partially inorganic barrier layers (B) to form one or more transparent radiation-curable (meth)acrylate layers and curing said layer or layers to form one or more radiation-cured (meth)acrylate layer (C); and
d. applying one or more thermally-curable coating compositions D on the one or more radiation-cured (meth)acrylate layer (C) to form one or more thermally-curable coating layers D and curing said layer or layers to form the one or more transparent, thermally-cured coating layers (D).

### Step a.

The substrate used in the above method can be any of the substrates as described above, but most preferably is a polymeric substrate, even more preferred a transparent, polymeric substrate selected from those as being described above.

The substrate, particularly the polymeric substrate may be surface treated, typically to enhance the adhesion between the support and layers provided thereon. Examples of such a surface treatment include but are not limited to a corona discharge treatment, a flame treatment, an UV treatment, a low-pressure plasma treatment, and an atmospheric plasma treatment.

The substrate may also be a pre-coated substrate e.g., comprising a planarization layer (P) as described above and which might be of the same kind as the radiation-cured (meth)acrylic layer (C) as described above.

If the substrate is provided with such planarization layer (P), the coating composition is preferably of the same kind as the radiation-curable coating composition C as described above. Thus, such coating layer is applied and cured in the same manner as will be described below for the radiation-curable coating composition C. The film-thickness of the cured planarization layer (P), if present, is preferably in the range from 0.5 to 10 μm, more preferred in the range from 1 to 5 μm.

### Step b.

The inorganic layer or layers are applied to the substrate by one or more methods selected from chemical vapor deposition (CVD), physical vapor deposition (PVD), atomic layer deposition (ALD) and sputtering to form one or more transparent, at least partially inorganic barrier layers (B).

The afore-mentioned methods are known to one of skill in the art. The CVD method to produce such layers is e.g., described in DE4035951 C1 or in CA2562914 A1 and references therein; the PVD method to produce such layers is e.g., described in EP0645470 A1 or in U.S. Pat. No. 5,900,271 A and references therein; and the sputtering method to produce such layers is e.g., described in US 2004/0005482 A1. Further reference is made to the above paragraphs describing the inorganic materials, namely the metal oxides, metal nitrides and metal oxynitrides and the literature thereon describing suitable application methods.

It is however most preferred to produce the transparent barrier layer or barrier layers by using the ALD method, if such layer are inorganic, preferably metal oxide layers only. This method is e.g., described in WO 2011/099858 A1 in detail.

If more than one inorganic layer is applied, it is possible, that between the two or more inorganic layers, e.g., applied by ALD, an organic layer containing organic molecule may be applied, e.g., applied by a molecular layer deposition technique.

The organic molecules used in the MLD technique to obtain such layer (B^{o}) have special functional groups able to be chemically-bound to the inorganic layer (Bⁱ), preferably the metal oxide layer (Bⁱ) such as thiol, disulfide, sulfide, selenol, amine, carboxylate, phosphate or phosphonate, or derivatives thereof.

Most preferred organic molecules to produce layer (B^{o}) belong to the family of aromatic thiols, as e.g., mercaptobenzoic acid, mercaptophenol, amino mercaptophenol and the like.

The application of such layers by MLD is e.g., described in WO 2015/030297 A1, WO 2015/188990 A2 and WO 2015/188992 A1 to which it is referred herewith.

### Step c.

In step c. a radiation-curable (meth)acrylic coating composition C is applied. This coating composition C comprises or consists of
i. one or more radiation-curable oligomeric (meth)acrylate-functional species;
ii. one or more radiation curable (meth)acrylate-functional monomers;
iii. one or more adhesion promoters;
iv. in case of UV-curing, one or more photoinitiators;
V. one or more compounds selected from UV absorbers, light stabilizers and antioxidants; and
vi. optionally one or more coatings additives.

These ingredients were described in detail above as well as their preferred contents in the coating composition C.

Since the radiation-curable coating composition C should be radiation-curable to form transparent radiation-cured (meth)acrylic layer(s) (C), this composition should preferably be substantially free from light-absorbing pigments and fillers.

Coating composition C may be applied by any suitable wet coating method. Suitable coating methods are, for example: spin-coating, blade coating, knife coating, kiss roll coating, cast coating, slot-orifice coating, calendar coating, die coating, dipping, brushing, casting with a bar, roller-coating, flow-coating, wire-coating, spray-coating, dip-coating, whirler-coating, cascade-coating, curtain-coating, air knife coating, gap coating, rotary screen, reverse roll coating, (revers) gravure coating, metering rod (Meyer bar) coating, slot die (Extrusion) coating, hot melt coating, roller coating, flexo coating. Suitable printing methods include: silk screen printing, relief printing such as flexographic printing, ink jet printing, intaglio printing such as direct gravure printing or offset gravure printing, lithographic printing such as offset printing, or stencil printing such as screen printing.

In case of the preferred UV curing, the curing wavelengths range, intensity and energy of the UV light are chosen depending on the photosensitivity of the coating composition C. Typically, the wavelengths are in the UV-A, UV-B and/or UV-C range. Preferably, radiation comprises light of wavelengths less than 400 nm, more preferred of wavelengths less than 380 nm. Particularly preferred is the use a UV mercury lamps as radiation source with an UV-Vis intensity of at least 600mJ/cm² and better of 800 mJ/cm².

To enhance the barrier function of the MLBF it is possible to repeat steps b. and c. one or more times.

### Step d.

In step d. a thermally-curable coating composition D is applied on the one or more radiation-cured (meth)acrylate layer (C) to form one or more thermally-curable coating layers D and curing said layer or layers to form the one or more transparent, thermally-cured coating layers (D).

Said coating composition D comprises or consists of
i. one or more hydroxyl-functional polymers selected from hydroxyl-functional and the fluoropolymers hydroxyl-functional poly(meth)acrylates;
ii. one or more polyisocyanates;
iii. one or more organic solvents;
iv. one or more compounds selected from UV absorbers, light stabilizers and antioxidants;
V. optionally one or more catalysts for catalyzing the reaction between i. and ii.; and
vi. optionally one or more coatings additives.

Ingredients i. and ii. were described above in detail. The UV absorbers, light stabilizers and antioxidants iv. can be selected from the same groups as disclosed for the radiation-curable coating composition C.

Typically, the coating compositions D comprise solvents iii. selected from the group of aprotic solvents such as esters, as e.g., butyl acetate and ethyl acetate; ketones such as methyl ethyl ketone; alkyl ethers such as methoxypropanol or glycolethers. aliphatic or aromatic hydrocarbon such has hexane, heptane, cyclohexane, benzene, toluene and xylene.

The catalysts v. that may be used to catalyze the crosslinking reaction between the hydroxyl-functional polymer(s) i. and the polyisocyanate(s) ii. are preferably selected from the group of tin based catalysts such as dibutyl tin dilaurate (DBTL) or dioctyl tin laurate. It may however be advantageous to use zinc or bismuth-based catalysts instead of the commonly used tin based catalysts. Zinc based catalysts are for example K-KAT-XK-622 and XK-614 from King Industries and Octa-Soligen® Zn catalysts from Borchers. Bismuth based catalysts are for example Borchi® Kat 0243, Borchi® Kat 0244 and Borchi® Kat 315 from Borchers.

The coating composition D may further comprise typical coatings additive, such as those described for radiation-curable coating composition C, which, contrary to those preferably used in radiation-curable coating composition C, are not radiation curable.

To avoid premature crosslinking at least ingredients i. and ii. are stored separately. The other ingredients can under storage conditions either be contained in i. or ii., particularly the solvents can be contained in i. and/or ii. Care should be taken that ingredients should not be reactive towards i., if stored in a premixture with i.; and the same applies to ingredients stored in a premixture with ii.

The ingredients i. to vi. above are not meant to be exclusive for other ingredients, such as reactive diluent, or reactive oligomers and polymers, being reactive towards ingredient ii. or the presence of crosslinking agents other than ii. However, it is preferred that the coating compositions D consist of ingredients i. to vi.

Since the thermally-curable coating composition D should be thermally-curable to form transparent thermally-cured layer(s) (D), this composition should preferably be substantially free from light-absorbing pigments and fillers.

Preferred amounts of ingredients i. to vi. as used in coating composition D are as follows:
i. preferably ranges from 10 to 60 wt.-%, most preferably from 20 to 50 wt.-%;
ii. preferably ranges from 5 to 20 wt.-%, most preferably from 7 to 15 wt.-%;
iii preferably ranges from 20 to 70 wt.-%, most preferably from 30 to wt.-%;
iv. preferably ranges from 0.1 to 10 wt.-%, most preferably from 0.2 to 5.0 wt.-%;
V. preferably ranges from 0 to 0.1 wt.-%, most preferably from 0.02 to 0.07 wt.-%;
vi. preferably ranges from 0 to 5 wt.-%, most preferably from 1 to 4 wt.-%; all wt.-% values being based on the total weight of the coating composition D.

The coating compositions D can be applied by any suitable wet coating method as already described for coating compositions C above.

The thus obtained layers can preferably be cured at a temperature in the range from preferably ambient temperature (25° C.) to 100° C., preferably in the range from 50° C. to 90° C., even more preferred from 65 to 85° C. for a period ranging from preferably 1 min to 120 min, more preferred 1 min to 60 min, even more preferred 1 min to 30 min, 1 min to 15 min or 2 min to 10 min. In general, the higher the curing temperature the shorter the curing time.

Use of the Multilayer Barrier Films and MLBF coated substrates

Such MLBF coated substrates can be used as protective sheets in photovoltaic applications. Such protective sheets can preferably be used in applications like solar cell modules as front protective sheet (frontsheet) or back protective sheet (backsheet) due to their lower weight, flexibility and advantageous costs; other possible applications are portable lighting devices, advance packaging for optoelectronics and displays like for example OLED screens.

### Examples

In the following the invention is described by means of Examples. If not stated otherwise, parts are all parts-by-weight and percentage values in relation of ingredients of compositions are in weight percent.

### Testing Procedures

### Testing of the Outer Curable/Cured Coating Composition D

Coating Compositions D have been kept for at least 24 h in closed brown glass bottles under air at a temperature of 23+2° C. with no control of humidity.

### Viscosity

The viscosity was determined with a torque rotating viscometer Brookfield CAP2000+ instrument 1 h after mixing at 100 rpm and 25° C.

### Glass Transition Temperature (DSC)

DSC was carried out at a heating rate of 10° C./min during the first heating cycle using a Mettler Toledo Star System TGA/DSC 1 instrument.

### Thermogravimetric Analysis (TGA)

TGA was carried out using a Mettler Toledo Star System TGA/DSC 1 instrument. The conditions were a heating rate of 10° C./min. Measurements were carried out under N₂ atmosphere.

### Dynamic Mechanical Analysis (DMA)

DMA was carried out using a Waters TA Instrument Discovery DMA 850. The measurements were carried out a temperature of 20° C.
(a) Storage Modulus
(b) Tensile Strength
(c) E-Modulus
(d) Elongation at Break

### Testing of the Multilayer Systems

All tests carried out on MLBF have been carried out after a conditioning time of 24 h at 23±2° C. and 50% relative humidity except for the UV stability data where no control of temperature and humidity was assured during sample conditioning.

### Thermal Stability/Damp Heat Test

The thermal stability of the MLBF coated substrate was tested by storing the MLBF coated substrate for 2000 h at 85° C. and 85% relative humidity.

### Cross-Cut Adhesion

Tape cross-cut adhesion was determined according to ASTM D3359-17 (6 blades at 2 mm distance).

### Haze, Clarity and Transmittance

Haze, clarity and transmittance were determined in accordance with ASTM 1003D: 2013.

### Yellow Index

The yellowing index was determined in accordance with DIN 6167:1980-01.

### UV Stability

The MLBF were subjected to a UV radiation of 1.5 kW/m², in a wavelength range of 295 to 400 nm for 820 h at a temperature of 70° C. and a relative humidity of 40%, using a Super UV-W161 metal halide instrument.

### Layer Thickness of the Coating Layers

The layer thickness was determined on the dry or where cured layers (P), (B), (C) and (D) by using a non-destructive dry-film measurement using for example a Coating Thickness Gauge like Byko-Test 4200 (available from BYK Instruments).

### Multilayer Systems and its Preparation

List of Ingredients

| Tradename | Chemical composition |
|---|---|
| Lumiflon ® | hydroxy-functional poly(fluoroethylene-vinylether) |
| LF916F | copolymer (solvent-free; OH value = 100 mg KOH/g, |
| | acid value: 0 mg KOH/g; Tg = 34° C.; Mp: 44.5° |
| | C.; fluorine content: 26.3 wt.-% |
| Zeffle ® | hydroxy-functional tetrafluoroethylene copolymer |
| GK570 | with a vinyl monomer (approx. 65 wt.-% in butyl |
| | acetate; OH value of solids content = 63 mg |
| | KOH/g; acid value: 3 mg KOH/g; Tg = 30° C.; |
| | fluorine content: 25.7 wt.-%) |
| Joncryl ® | hydroxy-functional acrylic resin (solvent-free; OH |
| 587 | value = 92 mg KOH/g; Tg = 57° C.; density = |
| | 1.16 g/cm³; Mn approx. 18,000 g/mol) |
| Joncryl ® | hydroxy-functional acrylic resin (solvent-free; OH |
| 963 | value = 130 mg KOH/g; Tg = −59° C.; density = |
| | 1.03 g/cm³; equivalent weight: 432; |
| | Mn approx. 24,000 g/mol) |
| Basonat ® | aliphatic polyisocyanate based on isocyanurate-modified |
| HI2000NG | hexamethylene diisocyanate (solvent-free; NCO approx. |
| | 23 wt.-% NCO; equivalent weight: 182; viscosity |
| | (23° C.) = 900-1500 mPas; Mn approx.7650 g/mol) |
| Basonat ® | aliphatic polyisocyanate based on isocyanurate-modified |
| HI100NG | hexamethylene diisocyanate (solvent-free; NCO approx. |
| | 22 wt.-%; NCO equivalent weight: 191; viscosity (23° |
| | C.) = 2500-4000 mPas; Mn approx. 8,000 g/mol) |
| Tinuvin ® | UV absorber: Hydroxy-phenyl-s-triazine with 18-20 |
| 477 | wt.-% 2-methoxy-1-propyl acetate |
| Tinuvin ® | HALS: Bis(1,2,2,6,6-pentamethyl-4-piperidyl) sebacate; |
| 292 | and methyl-1,2,2,6,6-pentamethyl-4-piperidyl sebacate |
| Tinuvin ® | UV absorber: 95% benzenepropanoic acid, 3-(2H- |
| 384 | benzotriazole-2-yl)-5-(1,1- dimethylethyl)-2-hydroxy-, |
| | C7-9-branced and linear alkyl esters, and 5% 1-methoxy- |
| | 2-propyl acetate |
| Laromer ® | aliphatic urethane acrylate (70 wt.-% in 4-tert-butyl- |
| UA 9072 | cyclohexyl acrylate) |
| Laromer ® | trimethylolpropane formal acrylate (100 wt.-%) |
| LR 8887 | |
| Laromer ® | methacrylated phosphoric acid ester |
| PA 9083 | |
| Byk UV 3535 | UV-curable silicone-free polyether leveling agent |
| Ominirad ® | photoinitiator; blend of oxy-phenyl-acetic acid 2-[2- |
| 754 | oxo-2-phenyl-acetoxy-ethoxy]-ethyl ester and oxy- |
| | phenyl-acetic acid 2-[2-hydroxy-ethoxy]-ethyl ester |
| MELINEX ® | polyethyleneterephthalate film with thickness of 125 μm |
| ST504 | |

### Transparent Polymeric Substrate (A)

As a transparent polymeric substrate, a crystal clear, high gloss, heat stabilized polyester film (polyethylene terephthalate; PET) having a film thickness of 125 μm and being available under the trademark MELINEX® ST504 from DuPont Tijin Films, was used.

### Transparent, at Least Partially Inorganic Barrier Layer (B)

The transparent, at least partially inorganic barrier layer (B) was applied on top of the transparent polymeric substrate by means of the atomic layer deposition (ALD) of aluminum oxide in a layer thickness of 100 nm as described for example in WO 2015/188990 A2 and WO 2015/188992 A1.

### Transparent Radiation-Cured (Meth)acrylate Layer (C)

Two different radiation curable (meth)acrylate compositions C1 and C2 were used to produce the transparent radiation-cured (meth)acrylate layer (C). The compositions C1 and C2, respectively, were applied on top of the transparent inorganic barrier layer (B) by means of an automatic bar coater metal blade (ZEHNTNER ZAA 2300) at a speed of approx. 20 mm/s and cured by means of a UV Mercury lamp (UVA2: 220 mJ/cm²; UV-Vis: 580 mJ/cm²; Speed: 5.6 m/min; Gap: 6 cm) to produce a transparent radiation-cured (meth)acrylate layer (C) having a dry layer thickness of about 22.5±2.5 μm.

The ingredients of compositions C1 and C2 as used are summarized in Table 1 below. The amounts are in parts by weight in their commercially available form.

TABLE 1

Radiation Curable
Acrylate
Compositions

| Ingredients | C1 | C2 |
|---|---|---|
| Laromer ® UA 9072 | 12 | 12.5 |
| Laromer ® LR 8887 | 28 | 28 |
| Isobornyl Acrylate | 49 | — |
| Tricyclodecanemethanol acrylate | — | 49 |
| 3-Methacryloxypropyltrimethoxysilane | 2 | — |
| 3-Glycidoxypropyltrimethoxysilane | — | 2 |
| Laromer ® PA 9083 | 2 | — |
| Byk UV 3535 | 2 | 2 |
| Ethyl phenyl(2,4,6-trimethylbenzoyl) | 3 | — |
| phosphinate | | |
| Phenylbis(2,4,6-trimethylbenzoyl) phosphine | — | 2 |
| oxide | | |
| Ominirad ® 754 | 1 | 1 |
| Tinuvin ® 477 | 1 | — |
| Tinuvin ® 292 | — | 1 |
| Tinuvin ® 384 | — | 2.5 |
| Sum of Ingredients | 100 | 100 |

Transparent, thermally-cured Outer Coating Layer (D)

Eight different thermally curable coating compositions (D1 to D8) were used to produce the transparent, thermally-cured outer coating layers (D) of Multilayer System Examples 1 to 9. The compositions were applied with a bar coater metal blade (20 mm/min) on top of the radiation-cured (meth)acrylate layer (C) and cured at 80° ° C. for 2 min (compositions D1 to D6) and 3 min (compositions D7 and D8), respectively, to produce a transparent, thermally-cured outer coating layer (D) having a dry layer thickness of 47.5±2.5 μm.

To produce the thermally curable coating compositions D1 to D8, the crosslinkable polymers as set out in Table 2 were mixed with the solvent component and subsequently the crosslinking agent was added to produce a homogeneous mixture.

Afterwards catalyst, UV absorber and light stabilizer were added. Compositions D3 and D6 were further diluted prior to their application with an additional amount of 6 g of butyl acetate.

TABLE 2
Thermally Curable Coating Compositions for forming the Outer Coating Layer (D) [amounts of ingredients in g]

| | | Thermally Curable Coating Compositions | | | | | | | |
|---|---|---|---|---|---|---|---|---|---|
| Ingredients | | D1 | D2 | D3** | D4 | D5 | D6** | D7 | D8 |
| Crosslinkable | Lumiflon ® LF916F | 42.13 | — | — | 16.0 | 10.0 | — | — | — |
| Polymer | Zeffle ® GK 570* | — | 32.5 | 32.5 | — | — | 4.00 | — | — |
| | Joncryl ® 587 | — | — | — | 4.0 | — | — | 20.00 | 20.00 |
| | Joncryl ® 963 | — | — | — | — | 10.0 | 16.00 | — | — |
| Solvents | Butyl acetate | — | 17.5 | 17.5 | — | | 2.15 | — | — |
| | Ethyl acetate | 37.66 | — | — | 17.88 | 17.88 | — | 20.00 | 20.00 |
| Crosslinking | Basonat ® HI2000NG | 13.72 | 6.35 | — | 6.38 | 7.4 | — | 6.12 | — |
| Agent | Basonat ® HI100NG | — | — | 6.64 | — | — | 7.76 | — | 6.12 |
| Catalyst | Tin octoate | 0.03 | — | — | 0.03 | 0.03 | 0.03 | 0.03 | 0.03 |
| UV absorber | Tinuvin ® 384 | 0.663 | 0.971 | 0.971 | 0.789 | 0.822 | 0.832 | 0.784 | 0.792 |
| Light Stabilizer | Tinuvin ® 292 | 0.265 | 0.388 | 0.388 | 0.263 | 0.274 | 0.278 | 0.261 | 0.264 |

Properties of Thermally Curable/Cured Coating Compositions

| Viscosity (after 1 h at 100 rpm, 25° C.) [mPas] | | 82.5 | 515 | 665 | 120 | 290 | 35 | 680 | 660 |
|---|---|---|---|---|---|---|---|---|---|
| Glass transition temperature (10° C./min) [° C.] | | 61.2 | 23.4 | 38.9 | 62.2 | 30.6 | 21.2 | 61.2 | 51.5 |
| TGA [%] | at 100° C. | −0.78 | −1.08 | −0,81 | −2.16 | −1.30 | −0.28 | −0.92 | −0.91 |
| (10° C./min; N₂) | at 150° C. | −2.2 | −2.6 | −2.1 | −6.0 | −2.82 | −0.49 | −3.3 | −3.3 |

| | | | | | | | | |
|---|---|---|---|---|---|---|---|---|
| Storage modulus (DMA at 20° C.) [MPa] | 583 | 873 | 956 | 1281 | 314 | 478 | 148 | 366 |
| Tensile Strength [MPa] | 2.94 | 1.58 | 1.92 | 15.5 | 15.5 | 10.7 | 2030 | 2040 |
| E-Modulus [MPa] | 152 | 43.4 | 28.3 | 793 | 6.1 | 2.3 | 11 | 10 |
| Elongation at break [%] | 8.6 | 18.9 | 20.8 | 3.7 | 26.6 | 31.9 | 0.5 | 0.4 |
| Used in Example | 1 and 2 | 3 | 4 | 5 | 6 | 7 | 8 | 9 |

*non-volatile (NV) content of Zeffle ® GK 570 (butyl acetate content specified under “Solvents” separately)
**Thermally Curable Coating Compositions D3 and D6 were supplemented with 6 g butyl acetate before application

In Table 3, the multilayer system architectures of Examples 1 to 9 and their properties are presented.

TABLE 3
Mulitlayer System Architecture of Examples 1 to 9 and Properties of the System

| | | Example | | | | | | | | |
|---|---|---|---|---|---|---|---|---|---|---|
| Layer | made of | 1 | 2 | 3 | 4 | 5 | 6 | 7 | 8 | 9 |
| (A) | PET | X | X | X | X | X | X | X | X | X |
| (B) | Al oxide | X | X | X | X | X | X | X | X | X |
| (C) | C1 | X | | | | X | X | X | X | X |
| | C2 | | X | X | X | | | | | |
| (D) | D1 | X | X | | | | | | | |
| | D2 | | | X | | | | | | |
| | D3 | | | | X | | | | | |
| | D4 | | | | | X | | | | |
| | D5 | | | | | | X | | | |
| | D6 | | | | | | | X | | |
| | D7 | | | | | | | | X | |
| | D8 | | | | | | | | | X |

| Properties of the | | Example | | | | | | | | |
|---|---|---|---|---|---|---|---|---|---|---|
| Multilayer System | | 1 | 2 | 3 | 4 | 5 | 6 | 7 | 8 | 9 |
| Thermal | 2000 h | NVD¹ | NVD | NVD | NVD | NVD | NVD | NVD | NVD | NVD |
| Stability | | | | | | | | | | |
| Cross-Cut | 0 h | 100 | 100 | 100 | 100 | >70 | >70 | >95 | 100 | 100 |
| Adhesion [%] | | | | | | | | | | |
| Haze | 0 h | 0.8 | 1.0 | 0.7 | 0.9 | 2.8 | 0.9 | 2.1 | 1.1 | 1.5 |
| | 2000 h | 1.2 | 2.7 | 1.2 | 3.1 | 3.4 | 4.1 | 3.3 | 4.0 | 3.4 |
| Clarity [%] | 0 h | 99.1 | 98.3 | 100 | 99.8 | 99.3 | 98.5 | 99.4 | 99.3 | 99.4 |
| | 2000 h | 98.8 | 94.6 | 99.5 | 99.5 | 99.2 | 98.1 | 99.3 | 98.9 | 98.4 |
| Transmittance | 0 h | 93.6 | 93.7 | 93.9 | 93.9 | 94.0 | 94.0 | 94.0 | 92.1 | 92.2 |
| [%] | 2000 h | 93.1 | 93.5 | 93.2 | 93.2 | 93.7 | 93.1 | 93.5 | 91.9 | 91.6 |
| Yellow Index | 0 h | 3.1 | 1.5 | 1.2 | 3.1 | 3.0 | 3.3 | 2.8 | 2.6 | 2.9 |
| | 2000 h | 5.1 | 3.6 | 2.9 | 4.4 | 5.5 | 6.3 | 7.7 | 4.3 | 4.6 |
| UV stability | ΔΥI | 1.20 | 0.58 | 0.82 | 1.68 | 0.99 | 1.26 | 1.1 | 11.4 | 14.9 |
| | dE* | <1.0 | <1.0 | <1.0 | <1.0 | <1.0 | <1.0 | <1.5 | 5.0 | 6.3 |
| | dL* | 0.24 | 0.32 | 0.26 | 0.31 | 0.25 | 0.74 | 1.32 | 0.25 | 0.35 |
| | ΔTransmittance | <5 | <5 | <2 | <2 | <5 | <3 | <5 | <20 | <20 |
| | [%] | | | | | | | | | |

¹NVD = no visual delamination

The results in Table 3 clearly show that there is no visual self-delamination for any of the inventive MLBF coated substrates after 2000 hours of thermal stability test. Furthermore, under the rather severe cross-cut adhesion test conditions those samples making only use of the fluoropolymers in layer (D) (Examples 1 to 4) show excellent adhesion in this test, since the integrity of the film is 100%. The same applies for the samples making only use of the hydroxyl-functional poly(meth)acrylates in layer (D). Preliminary results (not shown) indicate that the fluoropolymer containing layers (D) show better results in cross-cut adhesion after storage under elevated temperature and humidity.

All other results show that even under damp heat test conditions for 2000 h there are almost no to only low changes in haze, clarity, transmission, yellow index and UV stability, indicating an excellent long-term stability of the MLBF coated substrates.

1. A multilayer barrier film for coating a transparent polymeric substrate (A), the multilayer barrier film comprising in the order from (B) to (C) to (D) one or more transparent, at least partially inorganic barrier layers (B),
one or more transparent, radiation-cured (meth)acrylate layers (C), and
one or more transparent, thermally-cured coating layers (D),
wherein at least one layer (C) is in direct contact with one layer (D).

2. The multilayer barrier film according to claim 1, wherein
the thickness of the one or more barrier layers (B) is in a range of from 10 nm to 1000 nm; and/or
the thickness of the one or more radiation-cured (meth)acrylate layers (C) is in a range of from 1 μm to 100 μm; and/or
the thickness of the one or more thermally-cured coating layers (D) is in a range of from 10 to 100 μm.

3. The multilayer barrier film according to claim 1,
wherein the barrier layer (B) is preceded by a planarization layer (P), which is for planarizing the transparent polymeric substrate (A).

4. The multilayer barrier film according to claim 3,
wherein the thickness of the planarization layer (P) is in a range of from 1 to 30 μm.

5. The multilayer barrier film according to claim 1, wherein the barrier layer (B) is an inorganic layer (Bⁱ) formed by atomic layer deposition and consisting of one or more inorganic materials selected from the group consisting of metal oxides, metal nitrides, metal oxynitrides, and combinations thereof.

6. The multilayer barrier film according to claim 1, characterized in that wherein the barrier layer (B) consists of a layer stack (B1B^{o})ₙ(Bⁱ)ₜ, wherein Bⁱ is an inorganic layer, B^{o} is an organic layer formed by molecular layer deposition, n=1 to 100 and t=0 or 1, and the first of the n Bⁱ layers is formed on a planarization layer (P) or on a substrate (A).

7. The multilayer barrier film according to claim 1, wherein the one or more radiation-cured (meth)acrylate layers (C) are obtained by radiation-curing a radiation-curable coating composition C comprising at least one or more radiation-curable oligomeric (meth)acrylate-functional species and at least one or more radiation-curable (meth)acrylate-functional monomers.

8. The multilayer barrier film according to claim 1, wherein the stack of layers (B) and (C) are present a-times in form of [(B)-(C)]ₐ, with a=1 to 10.

9. The multilayer barrier film according to claim 1, wherein the one or more thermally cured coating layers (D) are polyurethane layers obtained by applying a coating composition D, the coating composition D comprising
at least one hydroxyl-functional polymer selected from the group consisting of radically polymerized, hydroxyl-functional fluoropolymers and hydroxy-functional poly(meth)acrylates; and
at least a crosslinker, selected from the group of polyisocyanates, onto the last applied radiation-cured (meth)acrylate layer (C) and thermally curing the obtained layer(s).

10. The multilayer barrier film according to claim 1, wherein layers (C) and/or (D) comprise at least one additive selected from the group consisting of UV-absorbers, light stabilizers and antioxidants.

11. A multilayer barrier film coated substrate, comprising a multilayer barrier film according to claim 1, wherein the multilayer barrier film coats the transparent polymeric substrate (A) in the order [substrate (A)]-(B)-(C)-(D).

12. The multilayer barrier film coated substrate according to claim 11, wherein it has a thickness in a range of from 20 μm to 300 μm.

13. The multilayer barrier film coated substrate according to claim 11, wherein the substrate is a transparent polyethylene terephthalate substrate.

14. A method for producing the multilayer barrier film as according to claim 1, comprising the steps of
a. providing a substrate; and forming the multilayer barrier film on the substrate by
b. applying one or more inorganic layers on the substrate by one or more methods selected from the group consisting of chemical vapor deposition (CVD), physical vapor deposition (PVD), atomic layer deposition (ALD) and sputtering to form one or more transparent, at least partially inorganic barrier layers (B);
c. applying one or more radiation-curable (meth)acrylic coating compositions C on the one or more transparent, at least partially inorganic barrier layers (B) to form one or more transparent radiation-curable (meth)acrylate layers and curing said layer or layers to form one or more radiation-cured (meth)acrylate layer (C); and
d. applying one or more thermally-curable coating compositions D on the one or more radiation-cured (meth)acrylate layer (C) to form one or more thermally-curable coating layers D and curing said layer or layers to form the one or more transparent, thermally-cured coating layers (D),
not excluding additional steps between steps a. and b., steps b. and c. and steps c. and d.

15. A method for producing a multilayer barrier film coated substrate by carrying out steps a. to d. according to claim 14, using a transparent polymeric substrate (A) as a substrate, wherein the multilayer barrier film coats the transparent polymeric substrate (A) in the order [substrate (A)]-(B)-(C)-(D), wherein the multilayer barrier film comprises in the order from (B) to (C) to (D)
one or more transparent, at least partially inorganic barrier layers (B),
one or more transparent, radiation-cured (meth)acrylate layers (C), and
one or more transparent, thermally-cured coating layers (D),
wherein at least one layer (C) is in direct contact with one layer (D).

16. A method of using the multilayer barrier film coated substrate or obtained according to the method of claim 15, wherein the method comprises using the multilayer barrier film coated substrate for photovoltaic applications.

17. A method of using the multilayer barrier film coated substrate according to claim 11, wherein the method comprises using the multilayer barrier film coated substrate for photovoltaic applications.
